(19) United States
(12) Patent Application Publication
(10) Pub. No.: US 2024/0308025 A1
(43) Pub. Date: Sep. 19, 2024

(54) DRESSING MEMBER

(71) Applicant: DISCO CORPORATION, Tokyo (JP)

(72) Inventor: Masaru NAGAMI, Tokyo (JP)

(21) Appl. No.: 18/586,818

(22) Filed: Feb. 26, 2024

(30) Foreign Application Priority Data
Mar. 14, 2023 (JP) 2023-039586

(51) Int. Cl. B24B 53/02; B24B 53/12

(52) U.S. Cl. CPC B24B 53/02; B24B 53/12

(57) ABSTRACT

A dressing member to be used in adjusting a grindstone tool in which abrasive grains are fixed includes a plurality of ceramic particles having cavities therein, and a bonding material that fixes the ceramic particles.

### BACKGROUND OF THE INVENTION

### Field of the Invention

The present invention relates to a dressing member for adjusting a grindstone tool in which abrasive grains are fixed.

### Description of the Related Art

There has been increasing the number of opportunities to process a wafer provided on a front surface thereof with devices such as integrated circuits, to a thin form, for realizing smaller and lighter devices. For example, the front surface side of a wafer is held by a chuck table, an annular tool called a grinding wheel and the chuck table are mutually rotated, and, while liquid such as pure water is supplied, the grinding wheel is pressed against the back surface side of the wafer, whereby the wafer is ground to be thinner (see, for example, Japanese Patent Laid-open No. 2000-288881).

The grinding wheel includes a plurality of grindstones in which abrasive grains formed of diamond or the like are fixed by a bonding material formed of resin or the like, and, at the time of grinding a workpiece such as a wafer, grinding surfaces (for example, lower surfaces) of the grindstones are brought into contact with a surface to be ground (for example, an upper surface) of the workpiece. At the grinding surfaces of the grindstones, the abrasive grains are appropriately exposed from the bonding material, and the workpiece is ground off by the exposed abrasive grains.

From such a principle of grinding, in a state in which the abrasive grains are not appropriately exposed from the bonding material at the grinding surfaces of the grindstones, the grinding ability of the grindstones becomes deficient, and excessive forces are liable to be exerted on the workpiece and the grindstones. As a result, there have been cases where defects such as chipping are generated in the workpiece. In addition, if there are deviations in height among the grinding surfaces of the plurality of grindstones, the workpiece would not be ground uniformly, and the quality of the products obtained would be lowered.

In view of this, an adjusting work called dressing for adjusting the state of the grindstones by intentionally consuming the grinding surface side of the grindstones is carried out before grinding a workpiece or during the grinding (see, for example, Japanese Patent Laid-open No. 2009-142906). In the dressing, in a state in which a grinding wheel is being rotated, the grinding surfaces of the grindstones are brought into contact with a dressing member (dressing board) for dressing. As a result, the abrasive grains of the grindstones are appropriately exposed from the bonding material (dressing), and the grinding surfaces of the plurality of grindstones are equalized in height (truing).

### SUMMARY OF THE INVENTION

The dressing member used in the dressing as described above is typically obtained by fixing abrasive grains formed of alumina, with a bonding material formed of resin or the like. On the other hand, in the dressing member, abrasive grains somewhat large in grain size are used in order to realize appropriate consumption of the grindstones. Hence, there has been a possibility that the abrasive grains falling off from the dressing member during dressing may be left on the grinding wheel or the chuck table or the like, resulting in defective processing such as scratches on the workpiece.

Accordingly, it is an object of the present invention to provide a dressing member with which the possibility of causing defective processing on a workpiece is suppressed to a low level.

In accordance with an aspect of the present invention, there is provided a dressing member to be used in adjusting a grindstone tool in which abrasive grains are fixed, the dressing member including a plurality of ceramic particles having cavities therein, and a bonding material that fixes the ceramic particles.

Preferably, a particle diameter of the ceramic particles is 20 to 300 μm. Preferably, a wall thickness of the ceramic particles is 2 to 100 μm. Preferably, a width of the cavities in the ceramic particles is 10 to 290 μm. Preferably, a material of the ceramic particles is aluminum silicate.

The dressing member according to the aspect of the present invention includes the hollow ceramic particles (the ceramic particles having cavities therein), and, during dressing, the ceramic particles are ground and crushed by the grindstone tool together with the bonding material. In other words, unlike the case of solid abrasive grains, the ceramic particles do not fall off as they are, but become small fragments.

Hence, even if the fragments of the ceramic particles are left on the grinding wheel, the chuck table, or the like, the fragments hardly become a cause of defects such as scratches when the workpiece is ground. Thus, according to the aspect of the present invention, there is provided a dressing member with which the possibility of causing defective processing on a workpiece is suppressed to a low level.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a grinding apparatus or the like;

FIG. 2 is a perspective view depicting a dressing member;

FIG. 3 is a sectional view depicting the dressing member;

FIG. 4 is a perspective view depicting the manner in which grindstones are dressed; and

FIG. 5 is a sectional view depicting the dressing member during dressing.

### DETAILED DESCRIPTION OF THE PREFERRED EMBODIMENT

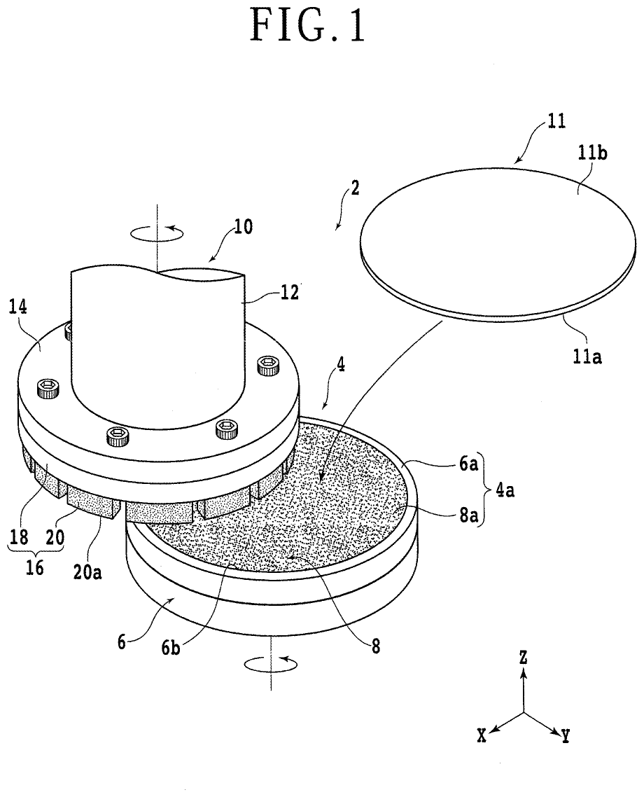

An embodiment of the present invention will be described below with reference to the attached drawings. First, a grinding apparatus or the like to be used in the present embodiment will be described. FIG. 1 is a perspective view depicting a grinding apparatus 2 or the like to be used in grinding a plate-shaped workpiece 11. Note that an X axis (first horizontal axis), a Y axis (a second horizontal axis), and a Z axis (vertical axis) which will be used in the following description are perpendicular to one another.

As depicted in FIG. 1, the grinding apparatus 2 includes a chuck table 4 configured to be able to hold the plate-shaped workpiece 11. The chuck table 4 includes a disk-shaped frame body 6 formed by use of, for example, ceramic. The frame body 6 is formed on an upper surface 6a side thereof with a recess 6b having a circular opening at an upper end thereof. In the recess 6b, there is fixed a holding plate 8 configured in a porous disk form by use of ceramic or the like.

An upper surface 8a of the holding plate 8 is configured, for example, in a shape corresponding to a side surface of a cone, and constitutes a holding surface 4a for holding the workpiece 11 or the like, together with the upper surface 6a of the frame body 6. Note that the height difference (difference in height) between the center of the upper surface 8a of the holding plate 8, which corresponds to the apex of the cone, and an outer edge of the upper surface 8a of the holding plate 8 is on the order of 10 to 30 μm.

A lower surface side of the holding plate 8 is connected to a suction source (not illustrated) such as an ejector through a channel (not illustrated) provided inside the frame body 6, a valve (not illustrated) disposed outside the frame body 6, and the like. Hence, when the workpiece 11 is mounted on the upper surface 8a of the holding plate 8 and then the valve is opened to cause a negative pressure of the suction source to act on the upper surface 8a of the holding plate 8, the workpiece 11 is sucked by the chuck table 4.

The workpiece 11 is, for example, a disk-shaped wafer configured by use of a semiconductor such as silicon (Si). In other words, the workpiece 11 has a circular front surface (first surface) 11a and a circular back surface (second surface) 11b on the side opposite to the front surface 11a. The front surface 11a side of the workpiece 11 is partitioned into a plurality of small regions by a plurality of intersecting streets (scheduled division lines), and a device such as an integrated circuit (IC) is formed in each of the small regions.

The grinding apparatus 2 in the present embodiment is to be used, for example, in grinding the workpiece 11 from the back surface 11b side. In this case, the front surface 11a side of the workpiece 11 is held by the chuck table 4. Hence, it is desirable to stick a protective member to the front surface 11a side of the workpiece 11 that is held by the chuck table 4.

As a result, a shock exerted on the front surface 11a when the workpiece 11 is ground from the back surface 11b side is mitigated by the protective member, so that the devices or the like of the workpiece 11 are protected. The protective member is typically a circular tape (film) having a diameter substantially equivalent to that of the workpiece 11, a resin substrate, a wafer of the same kind as or of a different kind from that of the workpiece 11, or the like.

Note that the circular wafer configured by use of the semiconductor such as Si is mentioned as an example of the workpiece 11 in the present embodiment, but the material, shape, structure, size, and the like of the workpiece 11 are not limited to those in this configuration. For example, a substrate or the like configured by use of such a material as other semiconductors, ceramic, resin, and metal may be used as the workpiece 11. Similarly, the kind, number, shape, structure, size, layout, and the like of the devices to be formed on the workpiece 11 are not limited to those in the above configuration. The workpiece 11 may not be formed with the devices.

A rotational drive source (not illustrated) such as a motor is connected to a lower part of the frame body 6. The chuck table 4 is rotated around a rotational axis parallel to the Z axis or slightly inclined relative to the Z axis, in such a manner that the center of the upper surface 8a is the center of rotation, by a force generated by the rotational drive source. In addition, the frame body 6 is supported by a chuck table moving mechanism (not illustrated) of a ball screw type or a turntable rotation type, and the chuck table 4 is moved along a plane (horizontal plane) including the X axis and the Y axis, by a force generated by the chuck table moving mechanism.

At a position above the chuck table 4, there is disposed a grinding unit 10. The grinding unit 10 includes, for example, a cylindrical spindle housing (not illustrated). In an inside space of the spindle housing, a columnar spindle 12 is accommodated. At a lower end part of the spindle 12, a disk-shaped mount 14 is provided. An annular grinding wheel 16 substantially equal in diameter to the mount 14 is fixed to a lower surface of the mount 14.

The grinding wheel 16 includes an annular wheel base 18 formed by use of metal such as stainless steel or aluminum. On an annular lower surface of the wheel base 18, a plurality of rectangular parallelepiped grindstones (a grindstone tool) 20 are fixed along the circumferential direction of the wheel base 18. Each of the grindstones 20 has a structure in which a plurality of abrasive grains formed of, for example, diamond are fixed by a bonding material formed of resin or the like.

The grindstones 20 include, for example, abrasive grains having a grain size of #280 to #8,000 defined by the Japanese Industrial Standards (JIS) R6001. In addition, the width (the length in the direction along a diameter of the grinding wheel 16) of the grindstone 20 is, for example, 1 to 5 mm. It is to be noted that the material, shape, structure, size, number, layout of the grindstones 20, the grain size of the abrasive grains contained in the grindstones 20, and the like are not necessarily limited to those in the above-mentioned configuration.

A rotational drive source (not illustrated) such as a motor is connected to an upper end side of the spindle 12. The grinding wheel 16 is rotated around a rotational axis parallel to the Z axis or slightly inclined relative to the Z axis, by a force generated by the rotational drive source. The spindle housing is supported, for example, by a grinding unit moving mechanism (not illustrated) of a ball screw type, and the grinding unit 10 is moved along the Z axis by a force generated by the grinding unit moving mechanism.

In the vicinity of the grinding wheel 16 or in the inside of the grinding wheel 16, there is provided a nozzle (not illustrated) configured in such a manner as to be able to supply grinding liquid (typically, water) to the workpiece 11, the grindstones 20, and the like. During grinding of the workpiece 11, the grindstones 20 are cooled by the grinding liquid supplied from the nozzle, and swarf generated from the workpiece 11 and the grindstones 20 is discharged to the exterior of the workpiece 11.

A controller (not illustrated) is connected to the various constituent elements of the grinding apparatus 2 described above. The controller is configured, for example, by use of a computer including a processing device and a storage device, and controls the operations of the above-mentioned constituent elements and the like in such a manner that the workpiece 11 is ground suitably.

The processing device is typically a central processing unit (CPU), and performs various kinds of processing necessary for controlling the above-mentioned constituent elements. The storage device includes, for example, a main storage device such as a dynamic random access memory (DRAM) and an auxiliary storage device such as a hard disk drive and a flash memory. Functions of the controller are realized, for example, by operations of the processing device according to software such as a program stored in the storage device.

At the time of grinding the workpiece 11 by the grinding apparatus 2 configured as above, first, the workpiece 11 is held by the chuck table 4. For example, the workpiece 11 is mounted on the holding surface 4a of the chuck table 4 in such a manner that the back surface 11b side is exposed to the upper side. In this state, the valve is opened to cause the negative pressure of the suction source to act on the holding surface 4a, and the workpiece 11 is then held under suction by the chuck table 4.

Next, the chuck table 4 is moved to a position directly under the grinding unit 10. Specifically, the positional relation between the grinding wheel 16 and the chuck table 4 is adjusted by the chuck table moving mechanism such that the intersection between an extension line of the rotational axis of the chuck table 4 and the back surface 11b, which is a surface to be ground, of the workpiece 11 is located at a position directly under the trajectory of the grindstones 20 when the grinding wheel 16 is rotated.

Thereafter, in a state in which the chuck table 4 and the grinding wheel 16 are being rotated, the grinding unit moving mechanism lowers the grinding unit 10 (grinding wheel 16). In other words, the grinding wheel 16 and the workpiece 11 are moved relative to each other in a direction intersecting the back surface 11b of the workpiece 11, while being mutually rotated. Besides, in this case, the liquid is supplied from the nozzle to the workpiece 11, the grindstones 20, and the like. Upon contact of the grindstones 20 with the workpiece 11 from the back surface 11b side, grinding of the workpiece 11 is started.

Incidentally, before grinding of the workpiece 11 according to the above-described flow or during the grinding of the workpiece 11, an adjusting work called dressing in which the grindstones 20 are intentionally consumed to adjust the state of the grindstones 20 is carried out. The dressing is realized, for example, by bringing lower surfaces 20a of the grindstones 20, which are grinding surfaces, into contact with a dressing member (dressing board) for dressing in a state in which the grinding wheel 16 is being rotated.

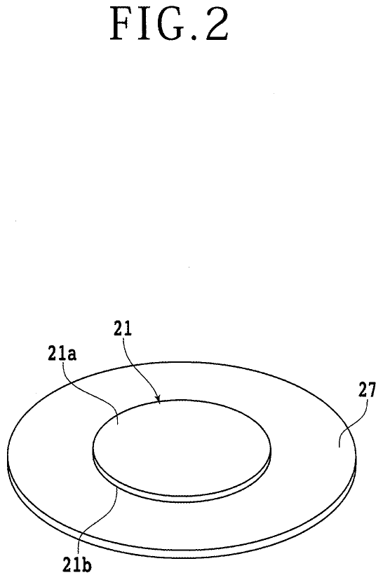

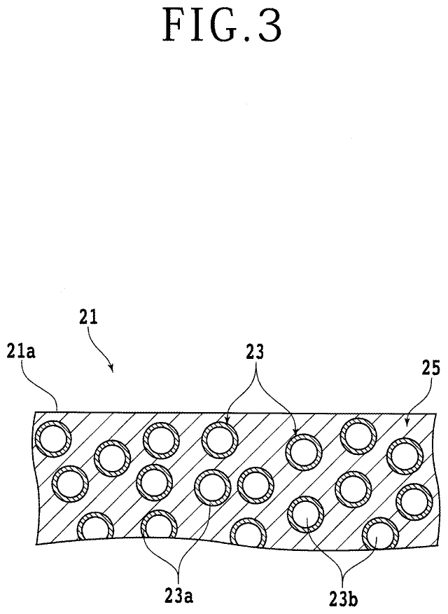

FIG. 2 is a perspective view depicting a dressing member (dressing board) 21, and FIG. 3 is a sectional view depicting the dressing member 21. As depicted in FIG. 2, the dressing member 21 is configured, for example, in the shape of a disk having a circular front surface (first surface) 21a and a circular back surface (second surface) 21b on the side opposite to the front surface 21a. It is to be noted, however, that the shape of the dressing member 21 is not necessarily limited to the shape in this configuration.

As depicted in FIG. 3, the dressing member 21 is formed by mixing hollow ceramic particles 23 and a bonding material 25 and solidifying the mixture by burning it. In other words, the dressing member 21 includes a plurality of the hollow ceramic particles 23 and the bonding material 25 for fixing the ceramic particles 23. The ceramic particle 23 has, for example, a shell 23a configured in a substantially spherical shape and a cavity 23b defined by an inside surface of the shell 23a.

As a main material of the ceramic particles 23 (shells 23a), for example, aluminum silicate containing silicon dioxide (SiO₂) and aluminum oxide (Al₂O₃) in desired proportions is adopted. As a result, a strength of the ceramic particles 23 suitable for the dressing member 21 is easily realized. It is to be noted, however, that the material of the ceramic particles 23 can freely be selected in such a range as to be able to realize the hollow ceramic particles 23 having a strength suitable for the dressing member 21. For example, the ceramic particle 23 may be configured substantially by use of only SiO₂.

The proportion of the mass (weight) of SiO₂ in aluminum silicate adopted as the material of the ceramic particles 23 is, for example, 50% to 70%, typically, approximately 60%, and the proportion of the mass of Al₂O₃ is, for example, 30% to 50%, typically approximately 40%. Commercial products of the ceramic particles 23 configured by use of aluminum silicate having such a composition include the E-SPHERES (registered trademark) series made by TAIHEIYO CEMENT CORPORATION.

The size (particle diameter) of the ceramic particles 23 is preferably 20 to 300 μm. In addition, the wall thickness of the ceramic particles 23 (the thickness of the shells 23a) is preferably 2 to 100 μm, and the width (diameter) of the cavities 23b of the ceramic particles 23 is preferably 10 to 290 μm. It is to be noted, however, that the sizes, shapes, and the like of each part of the ceramic particles 23 may not necessarily satisfy these conditions.

The sum of masses of all the ceramic particles 23 contained in the dressing member 21 is, for example, 20% to 80%, typically 60%, with respect to the sum of the mass of all the ceramic particles 23 and the mass of the bonding material 25. It is to be noted, however, that the sum of the masses of all the ceramic particles 23 contained in the dressing member 21 may not necessarily satisfy this condition, and may freely be set according to, for example, the performance required of the dressing member 21.

As the material of the bonding material 25, one that contains resin as a main constituent (a resin bond), one that contains vitreous silicon dioxide as a main constituent (a vitrified bond), or the like is adopted. In addition, the bonding material 25 may be formed therein with pores (not illustrated). It is to be noted, however, that the material, structure, and the like of the bonding material 25 are not necessarily limited to those in this configuration.

As depicted in FIG. 2, the plate-shaped dressing member 21 is used, for example, in the state of being supported by a support member 27. The support member 27 is configured, for example, in a disk shape by use of resin such as polyvinyl chloride (PVC), and the back surface 21b side of the dressing member 21 is fixed to the support member 27 with an adhesive or the like. The diameter of the support member 27 is typically larger than the diameter of the upper surface 8a (see FIG. 1) of the holding plate 8 of the chuck table 4.

It is to be noted, however, that the material, shape, size, and the like of the support member 27 are not necessarily limited to those in this configuration. For example, a film such as a dicing tape configured by use of resin may be used as the support member 27. Note that, in this case, an annular frame or the like may be fixed to an outer edge part of the support member 27.

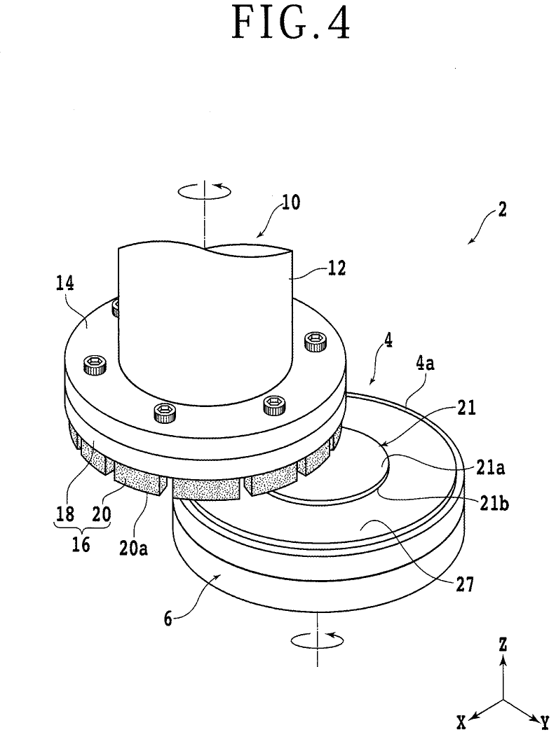

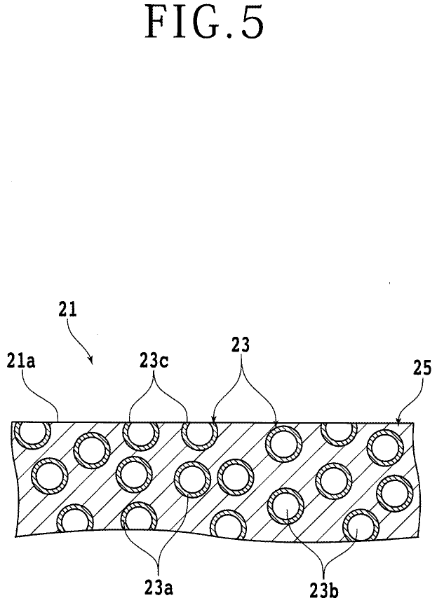

FIG. 4 is a perspective view depicting the manner in which the grindstones 20 are dressed by use of the dressing member 21, and FIG. 5 is a sectional view depicting the dressing member 21 during the dressing. At the time of carrying out the dressing of the grindstones 20, first, the dressing member 21 is held by the chuck table 4 (a holding step).

Specifically, the support member 27 is mounted on the holding surface 4a of the chuck table 4 in such a manner that the front surface 21a side of the dressing member 21 is exposed to the upper side. In this state, the valve is opened to cause the negative pressure of the suction source to act on the holding surface 4a, and the support member 27 is then sucked by the chuck table 4. In other words, the dressing member 21 is held by the chuck table 4 with the support member 27 therebetween.

Next, the chuck table 4 is moved to a position directly under the grinding unit 10 (an initial position adjusting step). Specifically, the positional relation between the grinding wheel 16 and the chuck table 4 is adjusted by the chuck table moving mechanism in such a manner that the intersection between an extension line of the rotational axis of the grinding wheel 16 and the front surface 21a of the dressing member 21 is located at a position directly under the trajectory of the grindstones 20 when the grinding wheel 16 is rotated.

Thereafter, in a state in which the chuck table 4 and the grinding wheel 16 are being rotated, the grinding unit moving mechanism lowers the grinding unit 10 (grinding wheel 16) (a dressing step). In other words, the grinding wheel 16 and the dressing member 21 are moved relative to each other in a direction intersecting the front surface 21a of the dressing member 21, while being mutually rotated. Besides, in this instance, the liquid is supplied from the nozzle to the dressing member 21, the grindstones 20, and the like.

Upon contact of the grindstones 20 with the front surface 21a of the dressing member 21, dressing of the grindstones 20 is started. As depicted in FIG. 5, when the dressing of the grindstones 20 progresses, the front surface 21a side of the dressing member 21 is gradually ground, and the ceramic particles 23 are exposed.

Here, the ceramic particles 23 in the present embodiment are formed to be hollow, and the strength of the ceramic particles 23 is lower than the strength of solid abrasive grains. In addition, the ceramic particles 23 in the present embodiment are configured by use of aluminum silicate which is softer than alumina. Hence, when the ceramic particles 23 are exposed to the front surface 21a of the dressing member 21, the exposed parts of the ceramic particles 23 are crushed, and end parts 23c of the shells 23a are exposed to the front surface 21a.

In the present embodiment, by the contact of the lower surface 20a of the grindstones 20 with the end parts 23c of the shells 23a, consumption of the grindstones 20 is accelerated. Note that the ceramic particles 23 do not fall off as they are like solid abrasive grains, but are crushed as described above as the dressing member 21 is consumed, to become small fragments. More specifically, the ceramic particles 23 become fragments smaller than the abrasive grains contained in the grindstones 20 which are used at the time of grinding the workpiece 11. Hence, when the workpiece 11 is ground, the fragments hardly become a cause of defects such as scratches.

As has been described above, the dressing member 21 according to the present embodiment contains the hollow ceramic particles 23 (the ceramic particles 23 having the cavities 23b therein), and, during dressing of the grindstones (the grindstone tool) 20, the ceramic particles 23 are ground and crushed by the grindstones 20, together with the bonding material 25. In other words, unlike the case of the solid abrasive grains, the ceramic particles 23 do not fall off as they are, but become the small fragments.

Hence, even if the fragments of the ceramic particles 23 are left on the grinding wheel 16, the chuck table 4, and the like, the fragments hardly become a cause of defects such as scratches, during grinding of the workpiece 11. Thus, according to the present embodiment, there is provided the dressing member 21 with which the possibility of causing defective processing on the workpiece 11 is suppressed to a low level.

Note that the present invention is not limited to the description of the above embodiment and can be carried out with various modifications. For example, in the above-described embodiment, the dressing member 21 is used at the time of dressing the grindstones (the grindstone tool) 20 contained in the grinding wheel 16, but the dressing member 21 may be used at the time of dressing another grindstone tool. For example, the dressing member 21 may be used at the time of adjusting an annular grindstone tool called a cutting blade for cutting the workpiece 11 or forming grooves in the workpiece 11.

Other than the above-mentioned points, the structures, methods, and the like concerning the above embodiment and modifications can be modified as required in carrying out the present invention insofar as the modifications do not depart from the scope of the object of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A dressing member to be used in adjusting a grindstone tool in which abrasive grains are fixed, the dressing member comprising:
a plurality of ceramic particles having cavities therein; and
a bonding material that fixes the ceramic particles.

2. The dressing member according to claim 1, wherein a particle diameter of the ceramic particles is 20 to 300 μm.

3. The dressing member according to claim 1, wherein a wall thickness of the ceramic particles is 2 to 100 μm.

4. The dressing member according to claim 3, wherein a width of the cavities in the ceramic particles is 10 to 290 μm.

5. The dressing member according to claim 1, wherein a material of the ceramic particles is aluminum silicate.

6. The dressing member according to claim 2, wherein a material of the ceramic particles is aluminum silicate.

7. The dressing member according to claim 3, wherein a material of the ceramic particles is aluminum silicate.

8. The dressing member according to claim 4, wherein a material of the ceramic particles is aluminum silicate.
